(19) United States
(12) Patent Application Publication
(10) Pub. No.: US 2003/0206122 A1
(43) Pub. Date: Nov. 6, 2003

(54) Computer keyboard having additional symbol keys

(76) Inventor: Harry E. Emerson, Succasunna, NJ (US)

Correspondence Address: HARRY E. EMERSON, 27 GARDEN COURT, SUCCASUNNA, NJ, 07876, US

(21) Appl. No.: 10/427,880

(22) Filed: May 1, 2003

Related U.S. Application Data
(60) Provisional application No. 60/377,511, filed on May 2, 2002.

(51) Int. Cl. H03M 11/00; H03K 17/94

(52) U.S. Cl. 341/22; 400/476

(57) ABSTRACT

A computer keyboard which can generate additional symbols not presently available from keyboards including the trademark and service mark symbols. A computer keyboard having additional symbol keys. A computer keyboard having symbol characters shared on keys of the numeric keypad.

This application claims the benefit of U.S. provisional patent application Serial No. 60/377,511, filed May 2, 2002.

### BACKGROUND OF THE INVENTION

1. Field of the Invention

The present invention relates to computer keyboards, including the nature of keys provided on the keyboard, the layout of those keys, and the functionality provided by those keys in relation to the computer system.

2. Description of the Prior Art

Computer keyboards have become standardized in their basic format for use with a variety of computers and computer operating systems. In particular, this document refers to computer keyboards compatible with computers designed according to Microsoft Corporation hardware specifications and the Intel Corporation microprocessor and system design (so called Wintel computers, an acronym referring to Microsoft Windows and Intel Corporation), and to keyboards compatible with computer operating systems capable of running on these computers, including the various Microsoft operating systems and varieties of the Unix operating system, especially Linux and its derivatives.

The following section describes the evolution of the computer keyboard from the introduction of the original IBM PC to today's current versions, and describes the function of the major keys and key groupings.

83-Key PC/XT Keyboard Layout

As illustrated in FIG. 1, the very first PC keyboard was the 83-key keyboard produced by IBM for the very first IBM PCs and PC/XTs in the early 1980s. This design was copied nearly verbatim by most of the early PC “clone” makers, and was the standard for PCs of this era. From a layout standpoint, however, there are numerous problems with the original 83-key layout, which caused many typists a great deal of frustration. Here are some of the main issues with this layout, when it is contrasted to more modem configurations:

Cramped Physical Grouping: It is a very “cramped” layout. All of the keys except the function keys are physically contiguous, giving the layout a very “busy” appearance. This is made worse by the fact that many keys are of odd sizes, and there is no clear vertical “dividing line” for the eye between the main typing area and the numeric keypad. Even the function keys are not separated very much from the rest of the layout. Overall, it looks like a “jumble of keys”. This may seem a trivial matter but has an impact on those learning to use the PC.

Poor <Shift> Key Size and Location: The <Shift> keys are rather small, and even worse, there is an extra key (backslash and vertical bar) between “Z” and the left <Shift> key, causing touch typists to accidentally hit this extra key when reaching for the left <Shift> key.

Poor <Enter> Key Size and Location: The <Enter> key is also rather small, and too far to the right, with an extra, rarely needed key (back-quote and tilde) between the main typing area and the <Enter> key. The <Enter> key doesn't line up vertically with the right <Shift> key.

Strange <Ctrl> Key Size and Position: Many users found the <Ctrl> key to be too large and in the place where they expected to find the <Caps Lock> key. In turn, the <Caps Lock> key is in an odd location.

No Dedicated Cursor and Navigation Keys: The only cursor and navigation keys are the ones on the numeric keypad. Since the cursor and navigation keys are needed almost all the time, this greatly reduced the utility of the numeric function of that keypad. (Remember that the most popular application in the early days of the PC was Lotus 1-2-3, a spreadsheet program used by financial people who needed both cursor movement keys and the numeric keypad.)

No Indicator LEDs: These early keyboards communicated unidirectionally with the system and could not accept the commands now used to control the indicator LEDs, so they included none. This caused much confusion, particularly given the frequency with which the <Num Lock> key needed to be pressed in order to flip between the cursor keys and the numeric keys. Some PC clone keyboards came out with indicator LEDs on them that were controlled by the keyboard itself to indicate the status of the <NumLock>, <CapsLock>, and <ScrollLock> keys. These mostly worked OK, but had the potential for becoming “out of sync” with what the system thought the state of the toggle modifier keys was.

Left-Side Function Keys: Many users disliked having the function keys on the left hand side of the keyboard, principally because early software would often provide visual cues on the bottom of the screen indicating what roles the different function keys would play in that application, and users wanted to see the function keys “line up” with these cues.

84-Key At Keyboard Layout

IBM received a lot of complaints about the first keyboard design and eventually made improvements to it. The first evolution of the keyboard was the 84-key keyboard layout introduced with the first IBM PC/AT, illustrated in FIG. 2. (The LED indicators are above the numeric keypad and not shown in this photo.) This is sometimes called the AT Keyboard. There are several definite improvements with this layout, compared to the 83-key keyboard:

Better Physical Grouping: The keyboard has three distinct key physical groups, with the numeric keypad placed distinctly to the right. The three groupings have clean vertical lines. The numeric keypad has been reorganized. Overall, the keyboard has a much more organized and understandable appearance.

Improved <Shift> and <Enter> Keys: The left <Shift> key, and the <Enter> key, have been enlarged, and the seldom-used “intervening” keys relocated.

LED Indicators: With the new internals of this keyboard (see below), LED indicators for the “lock” functions were added.

Extra “System Request” Key: This is the “84th key”. It was mostly used for special control operations for PCs operating in communication with mainframe computer systems.

However, many of the layout issues with the original design remained. The biggest concern that remained unaddressed was the continued sharing between the numeric keypad, and the cursor and navigation keys. The function keys are still on the left-hand side, and the <Ctrl> and <Caps Lock> keys are still different from what a typist would expect.

This keyboard was changed internally from the PC/XT model as well. The interface was made bidirectional, allowing the system to send commands to the keyboard, and enabling the control of the new LED indicators. The signaling and interface protocols created with this first PC/AT keyboard are still used today, even though the 84-key layout is no longer used, having been replaced by the “Enhanced” 101-key keyboard.

101-Key “Enhanced” Keyboard Layout

In 1986, IBM introduced the IBM PC/AT Model 339. Included in this last AT-family system was the new Enhanced 101-key keyboard illustrated in FIG. 3. This 101-key keyboard would become the de-facto standard for keyboards through the current day. Even today's 104-key Windows keyboards and variants with extra buttons and keys are based on this layout. The “Enhanced” keyboard was electrically the same as the 84-key AT keyboard, but featured a radically redesigned key layout. The major changes included these:

Dedicated Cursor and Navigation Keys: Finally, separate keys were provided for cursor control and navigation. This enabled the numeric keyboard to be used along with the cursor and navigation keys. The cursor keys were also made into an “inverted-T” configuration for easier movement between the “Up” key and the “Down” key with a single finger.

Relocated Function Keys: The function keys were moved from the left-hand side of the keyboard to a row along the top, and divided into groups of four for convenience.

Extra Function Keys: Two additional function keys, <F11> and <F12> were added to the keyboard.

Relocated <Esc> and <Caps Lock> Keys: The <Esc> key was moved back to the left-hand side of the keyboard, and placed up above the main typing area. The <Caps Lock> key was moved above the left <Shift> key.

a Extra <Ctrl> and <Alt> Keys: Additional <Ctrl> and <Alt> keys were added on the right side of the <Space Bar>.

Extra Numeric Keypad Keys: The numeric keypad was fitted with an additional <Enter> key, as well as the “/” (divide operator) that had been missing up to that point.

Compared with the 84-key keyboard the Enhanced keyboard layout was perceived by most users to be far superior. It was an immediate hit despite its one obvious inferiority to the AT keyboard due to the smaller main <Enter> key.

With these improvements, the 101-key keyboard layout became the standard, and was modified only slightly by the nearly identical 104-key Windows keyboard which is the standard now. Although the 101-key104-key designs are the “standard”, some manufacturers have introduced variations of the basic design to make minor improvements. For example, a common modification is to enlarge the <Enter>key back to its “84-key layout size”, and squeeze the backslash/vertical-pipe key between the “=/+” key and the <Backspace>.

102-Key “Enhanced” Keyboard Layouts

Several slightly modified versions of the regular American English 101-key Enhanced keyboard were created by IBM for by non-English PC users. These keyboards are virtually identical to the regular 101-key Enhanced keyboards, incorporating just slight differences from the regular U.S. keyboard. Considering the United Kingdom layout as an example, the following changes have been made:

The regular number “3” key now yields “£” instead of “#” when shifted.

The back-quote key yields the “-” (horizontal bar) symbol when shifted instead of a tilde (“˜”).

The main <Enter> key has been enlarged; it is now L-shaped again (though upsidedown}

An extra key (the 102^{nd} ) containing the supplanted “#” and “˜” symbols has been added to the left of the main <Enter> key. (This seems a step backwards given the complaints about an extra key in this location in the 83-key layout.)

Another step backwards: the backslash/vertical bar key has been relocated back to its former place—to the right of the left <Shift> key.

104-Key “Windows” Keyboard Layout

As Windows became the predominant operating system in the PC market, Microsoft realized that many common Windows functions had no simple keyboard shortcuts to activating them. Seizing their leadership position, they created a specification for a new variant of the 101-key keyboard that includes special keys to activate common Windows functions. This design is the 104-key “Windows” keyboard, illustrated in FIG. 4.

This layout is identical to the 101-key Enhanced layout with the exception of the additional three keys: one Windows key on either side of the <Space Bar>,and a Windows context menu (right-click) key to the right of the <Space Bar>. This layout makes room for them by stealing real estate from the <Alt>, <Ctrl> and <Space Bar> keys along the bottom of the keyboard. In addition to the new Windows keys, the particular keyboard model shown in the illustration of FIG. 4 incorporates the larger main <Enter> key, enabled by moving the backslash/vertical pipe key up one row, placed next to the now-smaller backspace key. Although the particular model as shown incorporates this <Enter> key modification, the majority of Windows keyboards on the market incorporate the <Enter> key layout of the 101-key Enhanced keyboard. The functions of the two types of Windows keys are as follows:

“Windows ” Keys: Two keys, one to the left of the <Space Bar> and one to the right, are used to activate various functions within the operating system. If either is pressed by itself, it puts the Windows task bar in the foreground and opens the Windows start menu. (Note that this is identical to the function performed by the key combination <Ctrl>+<Esc>). The Windows keys are also like modification keys, as they enable several “short cut” actions through special key combinations such as opening the Windows Explorer by simultaneously pressing a Windows key and the <E> key.

Context Menu Key: This key, on the right-hand side of the keyboard, is used to simulate right-clicking the mouse at its current location. Under standard Windows functionality, this opens up a context menu of commands relevant to the Window or object the mouse was over at the time the key was pressed.

Since the Windows keyboard offers some flexibility that the regular Enhanced layout does not, and its cost of production is virtually unchanged, it quickly replaced the Enhanced layout as the de-facto standard on most PCs. Most keyboards today, whether they are included with new PCs or sold separately, are some variation of the 104-key Windows keyboard layout.

Modern 104-key Windows Keyboards with Special Purpose Keys

Many specialty keyboards have extra keys or buttons, above and beyond the keys normally found on “standard” keyboards. These are becoming increasingly popular as companies look to provide convenience features on the keyboard, and possibly differentiate their offerings from those of competitors. Keyboards dubbed “Internet keyboards” or “multimedia keyboards” usually have at least some of these extras.

These special keys are usually provided in addition to the regular 104 keys of a standard Windows keyboard, squeezed in along the top of the keyboard or on the right-hand or left-hand side. They of course differ by keyboard type, however, they commonly fall into the following categories.

Internet Shortcuts: A series of buttons to implement common Internet functions, such as connecting to the 'net, or opening a web browser or email software.

Audio Controls: Buttons that let you raise or lower your PC's sound volume, mute the sound, and so on. Some also include buttons that implement standard CD player functions: start/stop, pause, next, previous and such. Some include a rotary volume control.

Mouse Controls: Buttons that simulate movement of the mouse, or mouse clicks.

An example of a 104-key Windows keyboard with additional special purpose keys is illustrated in FIG. 5. This Hewlett-Packard keyboard is just packed with extra buttons and features. These include numerous Internet buttons, audio controls, CD player controls, and a rotary volume control (visible in the upper right hand corner).

Programmable keyboards which allow the user to define the role of individual keys also typically have extra keys, which are used to enable programming modes. Also, some foreign-language keyboards have additional keys corresponding to special characters required for those languages.

Since “extra” keys are non-standard and differ for each keyboard, special drivers or software are required to enable the special functions. Otherwise, the operating system won't know what to do with the unexpected, non-standard scan codes, and will probably just ignore them. More popular keyboards may have support built into Windows, and some foreign-language keyboards may also have native support. Otherwise you will need driver software from the maker of the keyboard.

Description of the Major Types of Keys

This section describes the purpose and operation of the major types of keys found on the 101-key and 104-key standard keyboards. The primary typographic keys include the following:

Alphabetic Keys: The keys A through Z. Regular keypresses produce lower-case letters, and shifted keypresses create upper-case letters. <Caps Lock> reverses the <Shift> key functionality.

Numeric/Punctuation Keys: These are the numeric keys along the top of the keyboard, above the alphabetic keys. Shifted, they produce various punctuation and special symbols. The numerics are pretty much universal on English-language keyboards; the punctuation symbols can be different depending on region. For example, the “#” key in the United States is a “£” symbol in the United Kingdom.

Other Main Punctuation Keys: Most of the other punctuation keys on the keyboard are located just to the right of the alphanumeric keys mentioned above. While they have special meaning in some software applications, they are “just characters” most of the time.

“White Space” Keys: These include the primary (main) <Enter> key, the <Tab> key and the <Space Bar>. These keys are used for formatting text, and to delimit text entries and commands. Collectively they are often referred to as “white space” since they are characters that separate “real” characters without containing any information in and of themselves. There is also a secondary <Enter> key that is part of the numeric keypad.

<Delete> and <Backspace> Editing Keys: In text-based applications-or in text fields within other applications (for example, a Web browser)—these keys are usually used in conjunction to allow deleting of characters. The standard followed in most software is that the <Delete> key removes a character to the right of the insertion point, and the <Backspace> key removes a character to the left of the insertion point. In other contexts such as word processors and email programs, the <Delete> key may be used to delete or remove any type of object; in these applications, regions of text and objects may be selected, for example, by using the techniques described for the <Shift> key, and then deleted by pressing the <Delete> key.

One of the most important advances of the new 101-key “Enhanced” keyboard created by IBM was the creation of separate, dedicated cursor-control and navigation keys. These had formerly been accessible only by using the numeric keypad. On modern keyboards these important keys are generally placed between the numeric keypad and the main typing area. The cursor control and navigation keys are also still also available using the numeric keypad, of course, but this is rarely used today. This set of keys includes the following:

Arrow Keys: These keys permit motion in most software programs in any of the four standard directions that exist in two dimensions: up (north), down (south), left (west) and right (east). In many programs these perform functions similar to those that a mouse does, simulating two-dimensional movement. Some keyboards actually have eight arrow keys; the additional four keys are diagonals that correspond to the “northwest”, “northeast”, “southwest” and “southeast” directions. The default arrangement is an “inverted-T” configuration. Some keyboards may use instead a “diamond pattern”, with the up arrow key higher.

<Page Up> and <Page Down>: These keys (sometimes labeled “PgUp” and “PgDn”) are used in software programs primarily for one-dimensional scrolling, for example, to go up or down one page in a spreadsheet program, word-processing document, Web page and so on.

<Home> and <End>: The <Home> key is usually used to go to the left side of the current line in a document, and the <End> key to the right side. The current line is the line of text having the active cursor, meaning the location on screen where the next keyboard action will take place.

The keyboard contains several keys that serve primarily to alter the function or meaning of other keys. They are often used in combination with another key (typically by holding them down and then pressing the other key) or are typically used to set a particular keyboard state. These will be referred to as modification keys, grouped into two different sub-categories. The first are temporary modification keys, because they modify other keys only while held down. This includes:

<Shift> Keys: These two keys are near the bottom of the keyboard, one on either side of the main typing area. They enable access to capital letters, and also to the “alternate” functions printed on the keycaps above the unshifted symbol or function shown. So for example, holding the <Shift> key down and pressing the equal sign (“=”) generates a plus sign (“+”). The <Shift> keys also change the behavior of the function keys in most software programs; for example, <Shift>+<F6> is different than just <F6>. The <Shift> key functions within Windows applications to create a selected region of text or objects (or both) when used in conjunction with the navigation keys; holding the <Shift> key down while simultaneously pressing an arrow key, the <Home>, <End>, <Pageup>, or <PageDown> keys will create a selected region. A selected region can be deleted with the <Delete> key, or can be moved, copied or have other actions performed on it according to the capabilities of the software application being used.

<Ctrl> Keys: These are the “control keys”; one is located on either side of the typing area. Sometimes the keycap says “Control” instead of the shortened “Ctrl”. These keys are used in combination with regular alphanumeric keys and also the function keys to control special features and functions in software programs.

<Alt> Keys: These are the “alternate control keys”. They operate the same way the <Ctrl> keys do; their presence just lets complex software have more options. For example, <Alt>+<F6> can be a different function than <Ctrl>+<F6>. The <Alt> keys are also used for ASCII code generation.

<Insert>: In modern computing systems this key functions as a toggle key to switch between the normal “insert mode”, where all typed characters are automatically inserted, and “replace mode”, where typed characters replace those at the text insertion point. Historically it was used to insert a space in a text area each time it is pressed, but that usage is now rare.

The temporary modification keys can be combined if held down. For example, holding down <Shift>+<Ctrl>+ the up arrow in the Microsoft Word application will select the entire current paragraph.

The second sub-category contains locking modification keys. These are toggle keys—they change the function of other keys until they are pressed again to cancel the effect:

Caps Lock: When pressed, causes the function of the <Shift> keys to be reversed, but only for letter characters; other keys are unaffected. When active, the Caps Lock LED will be lit.

Num Lock: Enables the numbers on the numeric keypad when activated, and lights the Num Lock LED as well. When not active, the numeric keypad's keys generate cursor-control functions instead. This functionality dates back to the earliest PCs, which did not have dedicated cursor-control keys; today the cursor-control functions on the numeric keypad are redundant, which is why many people leave Num Lock always enabled.

Scroll Lock: Lights the Scroll Lock LED and causes some software programs to alter their behavior when certain other keys are pressed. In particular, when Scroll Lock is active, the cursor keys are often used to scroll the visible document rather than change position within it. This is not used nearly as much as the other two.

Lastly, the 101-key and 104-key keyboards include some miscellaneous keys not easily categorized; they are:

Function Keys: The function keys are a set of twelve numbered keys that are used by different software programs for a variety of different purposes. They are sometimes called programmable function keys or just F-keys or PF-keys. The original PC keyboard designs had 10 function keys, arranged in a 2×5 matrix on the left-hand side of the keyboard. With the introduction of the 101-key Enhanced keyboard, this was expanded to 12 keys, which were moved to a single row along the top of the keyboard. The exact duty of the function keys depends entirely on how the software chooses to interpret them.

<Escape>: The Escape key is usually used as an “exit” key of sorts by programs, to cancel commands or get out of something. It is also used in some contexts to change the meaning of subsequent characters.

<Print Screen/Sys Rq>: When pressed from DOS, this key causes the contents of the current screen of text to be sent to an attached printer. From within Windows, it copies the contents of the screen, in graphical format, to the Windows clipboard. The alternate use of this key is for the “system request” function. This is a historical command originally based on older IBM terminal designs, and is not really used any more.

<Pause/Break>: When pressed by itself, pauses the display or operation of some software programs. When pressed in combination with the <Ctrl> key, sends a “break” command that will interrupt some software programs or DOS commands. (You can do the same thing with <Ctrl>+C).

Key Groupings

The 101-key and 104-key keyboards are divided into seven major key groupings. Referring to FIG. 3, they are: a) the main alphanumeric (typewriter) section 20; b) the numeric cluster (also called the numeric keypad) 22; c) the function keys 24; d) the Escape key 26; e) the arrow cluster 28; f) the miscellaneous key group 30 comprising <PrintScreen>, <ScrollLock>, and <Pause>; and g) the navigation key group 32 comprising <Insert>, <Delete>, <Home>, <End>, <PageUp>, and <PageDown>.

Prior Art Deficiency and Opportunity for Improvement

As reported in the preceding narrative, there has been development and advancement in the design, functionality, and usability of the computer keyboard over the last two decades, driven primarily by deficiencies and difficulties experienced by the user community. However, not all needs and opportunities for improvement have been entirely obvious to previous developers, and the pretext of this patent application is that there remains room for improvement.

In particular, while the keyboard offers a small selection of symbols, being those sharing the numbers on the main keyboard plus those on a few other dedicated symbol keys, there still a quite a few symbols that would be advantageous to be able to access from the keyboard. For example, a significant percentage of businesses attempt to protect trade names and other trademarks in Internet communications such as press releases by denoting these items with “TM”. There is a TM symbol available to the computer users generating these Internet documents. However, since the great majority of computer users are unaware of how to insert these symbols into their documents, they simply suffix the trade name with “TM”. So, for example, press releases from Adobe Corporation, which uses “Adobe” as a trade name, show their trade name as “AdobeTm ”, no space, one word, as if AdobeTm were the name of the company.

The trademark symbol, along with other additional symbols of interest are incorporated into the two standard character sets which are available in most contemporary computer systems. The basic character set, specified by an ANSI standard (American National Standards Institute) uses eight bits to identify each character, thus having a potential of 256 individual characters. The “lower” seven bits (from zero to 127) are used to indicate all of the numbers, letters, and symbols that appear on the standard keyboard, and are specified by the ANSI standard. Character positions from 128 to 255 are referred to as the extended character set, and include a variety of symbols and non-English characters and accent marks. The implementations of specific characters and symbols in the extended character set is system-dependent.

Symbols of popular interest that are commonly available in the extended character set include: trademark, copyright, registered, the euro, the cent, the British pound, the yen, degree, plus/minus, times, divided by, the math function symbol, and the fractions one-quarter, one-half, and three quarters.

More relevant to today's computing world is the Unicode standard which incorporates tens of thousands of character representations from most of the world's languages, along with a broad variety of symbols, including those from the extended character set. The Unicode standard has been adopted by the World Wide Web Consortium, which specifies requirements for browsers, html, and so forth. In that browsers must now support Unicode, all major hardware and software vendors also provide support for Unicode in their systems. Unicode is implemented in fonts, such as the Arial font by Monotype Corporation.

In addition to the symbols available in the extended character set, symbols of popular interest that are available in Unicode fonts also include: the service mark, less than or equal to, greater than or equal to, infinity, not equal to, equivalent to, approximately equal to, square root, sum (capital sigma), pi, lambda, theta, the integral, and the card suits of hearts, spades, clubs, and diamonds. Beyond these, Unicode incorporates many other math and science symbols (the ohm, for example), several other fractions (thirds, fifths, sixths and eighths), and the smiley and sad faces, among an array of what seems like anything that anyone involved could ever think of (chess pieces, dingbats, ASCII control codes, and on, and on, and on).

Most of the symbol characters mentioned previously as being of popular interest, do not appear as a key on any computer keyboard; in particular, this applies to the registered symbol, the copyright symbol, the trademark symbol, and the service mark symbol.

There are many computer applications such as email programs, web browsers, web page editors, and word processors that are capable of displaying symbols from the extended character set and from Unicode fonts, and, in general, the operating systems themselves are capable of generating these symbols for display in an application. However, there is no standardization of the process between applications and operating systems for this capability. For example, the trademark symbol is available in the Microsoft Windows operating system default font at character position 153. A user of a Microsoft Windows system can enter the TM symbol by pressing the keyboard Alt key while typing the numbers 0153 on the numeric keypad. As another example, Microsoft Word offers a menu option Insert/Symbol which produces a dialog box containing an array of available symbols. One must then select a Unicode font from a drop-down selection box containing a list of all the fonts installed on the system. When a Unicode font is selected a second listbox appears from which the user must choose “letter like symbols”. The symbols now available appear in the array of available symbols. One can then select the TM symbol and click a control button to insert it into the document.

The above methods, although available, require knowledge and sophistication in the art beyond that of the average computer user, and thus do not satisfy the needs of the majority of computer users who wish to enter into their documents symbol characters which are not available on the keyboard.

Because of the deficiency of the current keyboard design, there remains a need in the art for a keyboard design having a simple and straightforward means of entering additional symbol characters into a user's document.

### SUMMARY OF THE INVENTION

The present invention provides a simple means for computer users to enter symbol characters into their documents which are in addition to the symbol characters presently available on the standard 101-key/104-key keyboards. This invention provides multiple means to accomplish this objective: in one embodiment the keyboard is provided with an additional row of keys containing symbols. The new keys respond to the keyboard Shift key, giving access to two new symbols per new key. The new row of keys is positioned above the row of number/symbol keys which now occupy the top row of the typewriter-style typographic keys of the main keyboard. The row of function keys is displaced to another position to accommodate this new row of keys.

In another embodiment, the ten numbers on the shared number/symbol keys are replaced with ten new symbols. The keyboard already has duplicates of these numbers on the numeric keypad, and so this embodiment can be implemented with no rearrangement of the overall keyboard design.

In still another embodiment, up to eleven new symbols are shared on the numeric and decimal point keys of the numeric keypad, replacing the shared cursor arrow and navigation functions. The Num Locks key shifts between accessibility to the numbers and the new symbols, with the Num Locks operation being that, while the Num Locks key is on, and the associated Num Locks indicator light is on, access is provided to the numbers, otherwise access is provided to the symbols. In addition to the eleven number keys (zero through nine, plus the period), other keys on the numeric keypad could also be used for shared functions with symbol characters, and an expanded numeric cluster could offer even more keys that could be shared with symbols.

In a similar arrangement, which is the preferred embodiment, symbols are shared on keys in the numeric cluster, but the NUM LOCKS key is replaced with a SYMBOL LOCK key which enters the numeric keypad into the SYMBOL mode. The use of the NUM LOCK key for this application presents the confusing implication that only number keys are being shifted to an alternate function. The replacement of the NUM LOCKS key with a SYMBOL LOCK key allows the SYMBOL mode to be extended unambiguously to any key in the numeric keypad without any confusion. While in the Symbol mode, typing any key of the numeric keypad having a shared symbol character generates that symbol character rather than the shared number. The SYMBOL LOCK key has an indicator light associated with it, and the indicator light turns on when the numeric keypad is in the SYMBOL mode. When the numeric keypad is not in the SYMBOL mode, it is in the numeric mode.

More than one of these embodiments can be implemented in a particular computer keyboard design.

With any of these new arrangements a user can simply and easily enter additional symbol characters into their documents simply by typing the key for the desired symbol.

### BRIEF DESCRIPTION OF THE DRAWINGS

The invention will be more fully understood when reference is had to the following detailed description of the preferred embodiment of the invention and the accompanying drawings, in which:

FIG. 1 is an illustration of the 83-key original IBM PC keyboard;

FIG. 2 is an illustration of the 84-key IBM PC/AT keyboard;

FIG. 3 is an illustration of the 101-key Enhanced IBM keyboard;

FIG. 4 is an illustration of the 104-key “Windows” keyboard;

FIG. 5 is an illustration of a contemporary “multimedia” keyboard; and

FIG. 6 is an illustration of a keyboard Numeric Cluster having a Symbol Lock key and new symbol characters shared on numeric and other keys.

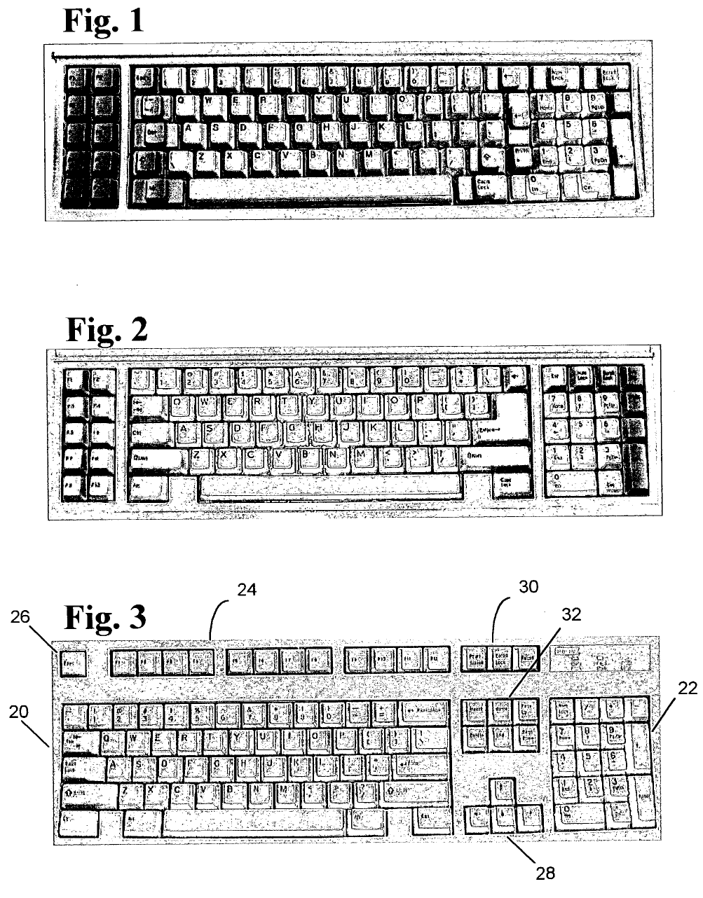

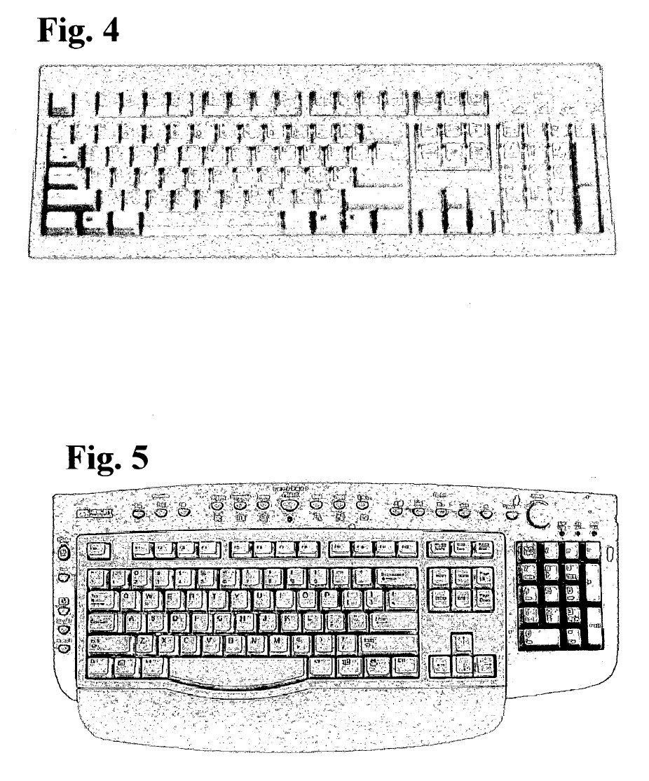

### DETAILED DESCRIPTION OF THE INVENTION

The present invention provides a simple means for computer users to enter new symbol characters, previously unavailable from the keyboard, into their documents interspersed with standard text. This invention provides for a keyboard having additional symbol characters placed on keys for ready access by the user. Symbol characters accessible from these keys are typographic characters that can be displayed on a screen, printed on a printing device, stored in documents and files, and transmitted electronically, the same as any other typographic character. In one embodiment, the keys to be used for these new symbol characters are new keys, preferably a new row of keys positioned immediately above the main keyboard number and symbol keys; in another embodiment, the keys to be used for these new symbols can be the main keyboard shared number and symbol keys with the new symbol characters replacing the numbers zero to nine.

In the preferred embodiment, these new symbol characters are shared on the keys of the Numeric Cluster, replacing the cursor arrow and navigation functions traditionally placed on these keys. This arrangement may take advantage of an expanded Numeric Cluster which has been expanded with the placement of additional keys for other reasons. In this preferred embodiment, the Num Locks key may be replaced with a Symbol Lock key, operating in the reverse of the Num Locks key. Activation of the Symbol Lock key activates the keyboard Numeric Cluster into the Symbol mode of operation. Whereas the Num Locks key enters the Numeric Cluster keys into the numeric mode when the Num Locks key is activated and its associated indicator light is turned on, the Symbol Lock key enters the Numeric Cluster keys into the Symbol mode when the Symbol Lock key is activated and its associated indicator light is turned on. Numeric Cluster keys having shared symbol characters will cause the keyboard to send appropriate messages to the computer operating software when those keys are pressed in the Symbol mode of operation, causing the computer's operating software to present the associated symbol characters on-screen. The messages being sent by the keyboard to the computer's operating software may include the name of the font from which the symbol is to be retrieved, and may specify the color that the symbol character is to be rendered in, in addition to other attributes of the symbol character that may be specified in the messages. Upon deactivation of the Symbol Lock key, the Numeric Cluster enters the numeric mode in which the numbers associated with each of these keys are presented on-screen by the same messaging process just mentioned, the messages now indicating that the numeric characters are those to be presented.

The available symbols mentioned previously can be categorized as those of general consumer and business interest, and those of math and science interest. While not intended to be an exclusive list, the following listing illustrates this categorization.

CONSUMER AND BUSINESS: trademark, copyright, registered, service mark, euro, cents, British pound, yen, degree, the fractions one-quarter, one-half, and three quarters, and the card suits of hearts, spades, clubs, and diamonds.

MATH AND SCIENCE: plus/minus, times, divided by, less than or equal to, greater than or equal to, not equal to, equivalent to, approximately equal to, infinity, the function, the integral, sum (capital sigma), pi, lambda, theta, and square root.

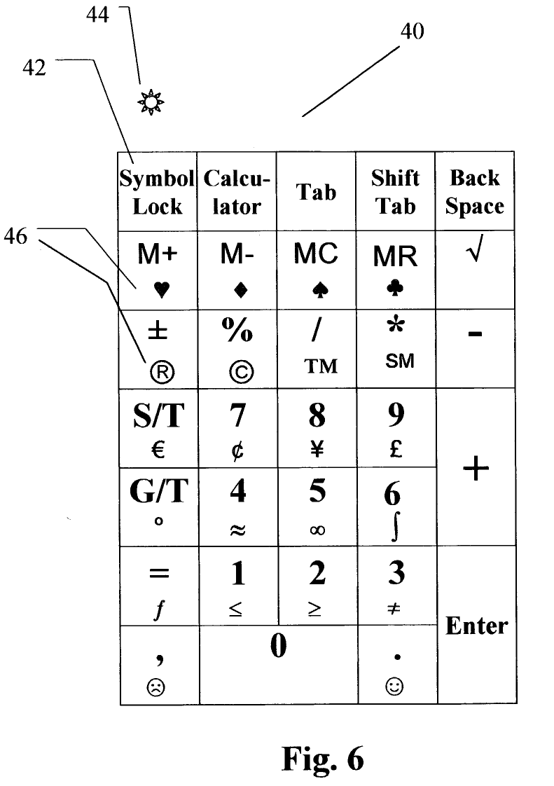

FIG. 6 illustrates the Numeric Cluster of a keyboard to indicate the manner in which the preferred embodiment of this invention may be implemented. Referring to FIG. 6, the Numeric Cluster is shown generally at 40, and incorporates a Symbol Lock key 42 having associated with it an indicator light 44. Although any of the keys in the Numeric Cluster could have symbol characters shared on them, this drawing illustrates a Numeric Cluster in which some keys and not others have been selected to share symbol characters for reasons of layout, design, and ease of use. The quantity of keys available for sharing with additional symbol characters, and the particular keys selected for this purpose are irrelevant to the purpose of this patent application. Identifier 46 indicates some of the symbols shared on keys in this Numeric Cluster; in particular, identifier 46 points to a heart symbol, and to a registered trademark symbol, but its use is intended to draw attention to the fact that many keys have new symbol characters sharing the functions or numbers that also appear on the keycap. For example, the heart symbol is shared on a key which also has a memory function M+, the registered trademark symbol is shared on a key which also has a plus-minus mathematical operation, and the cent sign is shared on a key which also has the number seven. In the illustration of FIG. 6, twenty-two keys share numeric and mathematical functions with new symbol characters.

The general nature of the operation of a keyboard is as follows: messages are generated by the keyboard electronics in response to a key press, the keyboard electronics delivers the messages to the computer operating system via a keyboard driver software component, and the computer operating system delivers the messages to the software application which presents the typed characters on the computer's screen.

There are several contemporary computer hardware designs and operating systems. For example, there are currently a variety of Microsoft Windows operating systems in use, the BeOS (the Be Operating System), the Apple MacIntosh operating system, a wide variety of UNIX operating systems and derivatives including SunOS (Sun Microsystems), HPUX (Hewlett Packard), and LINUX. Each hardware and software system presents a unique method of implementing keyboard functions into the overall system by the use of keyboard driver software, system messages, etc. In addition, the keyboard functions of this invention could be implemented by hardware and operating system software not yet in existence. Therefore, the precise nature of the associated keyboard driver software and messages to be sent to the operating system or to a software application to indicate the operation of an individual key, turning the Symbol mode on or off, etc. are beyond the scope of this patent application. It is ample to point out that the methods and means to implement such functionality are well known in the art, and individuals skilled in the art would be capable of implementing a system which could function according to this invention.

Having thus described the invention in rather full detail, it will be understood that such detail need not be strictly adhered to, but that further changes and modifications may suggest themselves to one skilled in the art falling within the scope of the present invention as defined by the subjoined claims.

What is claimed is:

1. A computer keyboard having keys for generating displayable characters in which one of said keys generates the symbol character for the business term “registered”, consisting of the letter R inside of a circle.

2. A computer keyboard having keys for generating displayable characters in which one of said keys generates the symbol character for the business term “copyright”, consisting of the letter C inside of a circle.

3. A computer keyboard having keys for generating displayable characters in which one of said keys generates the symbol character for the business term “trademark”,consisting of the letters TM and presented as a superscript character.

4. A computer keyboard having keys for generating displayable characters in which one of said keys generates the symbol character for the business term “service mark”, consisting of the letters SM and presented as a superscript character.

5. A computer keyboard having keys for generating displayable characters, comprising:
a. a main keyboard grouping of approximately 48 typographic keys and 13 control keys such as the Enter key, Tab key, and Backspace key;
b. a row of number keys of said main keyboard grouping incorporating keys having the numbers zero to nine; and
c. a row of symbol keys immediately above said row of number keys, said symbol keys having additional symbol characters to those otherwise available on the keyboard.

6. A computer keyboard having keys for generating displayable characters, comprising:
a. a main keyboard grouping of approximately 48 typographic keys and 13 control keys such as the Enter key, Tab key, and Backspace key, wherein each of the keys characteristically having the numbers zero through nine have an additional symbol character to those otherwise available on the keyboard instead of said numbers.

7. A computer keyboard having keys for generating displayable characters, comprising:
a. a main keyboard grouping of approximately 48 typographic keys and 13 control keys such as the Enter key, Tab key, and Backspace key;
b. a numeric cluster of keys positioned to the right of said main keyboard grouping of keys, said numeric cluster incorporating keys having the numbers zero through nine; and
c. said keys of said numeric cluster also having additional symbol characters to those otherwise available on the keyboard.

8. A computer keyboard having keys for generating displayable characters as recited in claim 7, further comprising:
a. a Symbol Lock mode key;
b. said keyboard functioning within a computer system by generating messages to the computer operating software, which messages indicate the appropriate computer system response to the activation or striking of a key such as by indicating a character to be presented on the computer system's display screen or by indicating a mode of operation to be engaged; and
c. said Symbol Lock mode key causing the keyboard to function in Symbol mode by sending appropriate messages to the computer's operating software such that when any of said numeric cluster keys also having a symbol character are struck while in said Symbol mode, said symbol characters will be presented on the computer's display screen.

9. A computer keyboard as recited in claim 8 further comprising an indicator light associated with said Symbol Lock mode key, said indicator light arranged to turn on when said Symbol Lock mode key and the associated numeric cluster is activated into the Symbol mode, and to turn off when said Symbol Lock mode key is deactivated and the numeric cluster is returned to its numeric mode.

10. A computer keyboard as recited in claim 8 wherein said messages include the font name to be used to generate said symbol character.

11. A computer keyboard as recited in claim 10 wherein said messages also include font attributes such as color, to be associated with said symbol character.
